(19) United States
(12) Patent Application Publication
(10) Pub. No.: US 2012/0164781 A1
(43) Pub. Date: Jun. 28, 2012

(54) Disordered Nanowire Solar Cell

(75) Inventors: Robert A. Street, Palo Alto, CA (US); William S. Wong, San Carlos, CA (US)

(73) Assignee: Palo Alto Research Center Incorporated, Palo Alto, CA (US)

(21) Appl. No.: 13/410,224

(22) Filed: Mar. 1, 2012

Related U.S. Application Data
(62) Division of application No. 12/579,379, filed on Oct. 14, 2009.

(51) Int. Cl. H01L 31/105; H01L 31/18

(52) U.S. Cl. 438/72; 438/87; 257/E31.061; 257/E31.127

(57) ABSTRACT

A disordered nanowire solar cell includes doped silicon nanowires disposed in a disordered nanowire mat, a thin (e.g., 50 nm) p-i-n coating layer formed on the surface of the silicon nanowires, and a conformal conductive layer disposed on the upper (e.g., n-doped) layer of the p-i-n coating layer. The disordered nanowire mat is grown from a seed layer using VLS processing at a high temperature (e.g., 450° C.), whereby the crystalline silicon nanowires assume a random interwoven pattern that enhances light scattering. Light scattered by the nanowires is absorbed by p-i-n layer, causing, e.g., electrons to pass along the nanowires to the first electrode layer, and holes to pass through the conformal conductive layer to an optional upper electrode layer. Fabrication of the disordered nanowire solar cell is large-area compatible.

### RELATED APPLICATIONS

This application is a divisional of U.S. patent application Ser. No. 12/579,379, entitled “Disordered Nanowire Solar Cell” filed Oct. 14, 2009.

### FIELD OF THE INVENTION

This invention relates to semiconductor devices, and more particularly, to vertically structured solar cells.

### BACKGROUND OF THE INVENTION

A photovoltaic cell is a component in which light is converted directly into electric energy by the photovoltaic effect. A solar cell is a photovoltaic cell that is intended specifically to capture energy from sunlight. First generation solar cells consist of large-area, high quality and single junction devices that involve high energy and labor inputs, which prevent any significant progress in reducing production costs. Second generation solar cells, which are currently in mass production, include “thin-film” solar cells made by depositing one or more thin-film (i.e., from a few nanometers to tens of micrometers) layers of photovoltaic material on a substrate.

FIG. 6 is a graph illustrating that optical absorption and charge collection have opposite dependence on device thickness in a conventional planar cell. This graph illustrates that a solar cell must both maximize the absorption of sunlight and efficiently separate and collect the charge. Absorption requires thick material, but charge collection is highest in thin materials, so that some compromise must be made in order to produce an operable solar cell.

FIG. 7 is a simplified diagram showing an exemplary vertically structured solar cell 50, which includes upper and lower electrode plates 51 and 52, respectively, and conductive rods 53 and 54 extending from electrode plates 51 and 52, respectively, into a centrally disposed charge collection material 55. Some of the light beams B entering central charge collection material 55 are absorbed, and the resulting electrons (e) and holes (h) flow along the respective rods 53 and 54 to electrode plates 51 and 52, respectively, thereby generating an electrical current and a voltage. Vertically structured solar cells are currently recognized as having an intrinsic advantage over thin-film devices because absorption and the charge collection are orthogonal in the vertically structured cell, and controlled by different dimensions, which can be optimized separately.

Vertically structured solar cells are particularly useful for low mobility, low charge collection material, such as polycrystalline and amorphous materials because the ability to reduce the collection length without affecting the optical absorption, greatly increases the cell efficiency. Successful demonstrations of vertical solar cells include the organic bulk heterojunction (BHJ) cells and highly ordered core/shell silicon nanowire structure cells. Organic BHJ cells are those in which two dissimilar materials are used to generate the bias field and induce charge separation between generated electrons and holes. The BHJ cell is an excellent demonstration of the advantages of the vertical cell, since a planar junction device has minimal solar cell response. However, the BHJ cell may never exceed 10% efficiency and many organic materials have significant long term stability issues due to their chemical interactions with volatile compounds in the air. The highly ordered core/shell silicon nanowire structure makes a high efficiency cell, but does not have much advantage over conventional silicon photovoltaic (PV) cells because the cost is no less than a convention silicon cell and the resulting efficiency is no higher.

What is needed is a low-cost vertically structured solar cell that exhibits both high light absorption and high charge collection, and also addresses the long term stability issues associated with conventional technologies.

### SUMMARY OF THE INVENTION

The present invention is directed to a vertically structured, disordered nanowire solar cell that includes doped silicon nanowires disposed in a disordered nanowire mat, and a thin (e.g., 50 nm) p-i-n coating layer formed on the surface of the silicon nanowires. The disordered nanowire solar cell addresses the problems associated with conventional vertical solar cells in that the disordered nanowire mat serves both as a highly efficient optical scattering structure and as a support structure for the p-i-n coating layer. That is, the disordered nanowire mat operates on the principle that the random interwoven pattern of the doped crystalline silicon nanowires significantly scatters the incident light, causing each photon interacts with many nanowires before being absorbed by the p-i-n coating layer. In addition, the large amount of surface area provided by the disordered nanowire mat facilitates the formation of a thin a-Si or a-SiGe p-i-n coating layer over a large effective area that that of conventional cells, thereby both greatly increasing light absorption and effectively eliminating the stability problems associated with thicker a-Si p-i-n layers.

According to an embodiment of the present invention, a disordered nanowire solar cell includes a substantially planar lower electrode layer, a disordered nanowire mat, including multiple doped silicon nanowires extending upwards from the lower electrode layer, a p-i-n coating layer formed on the surface of the nanowires, and a conformal conductive layer disposed on and extending above the p-i-n coating layer. The lower electrode layer includes a seed layer used to form the nanowires, and an optional conductive layer that is electrically connected to the p-i-n coating layer by way of the plurality of nanowires. Conformal conductive layer includes a conductive material deposited in a way that conformally coats portions of p-i-n coating layer disposed on the free ends and body of each nanowire in order to collect charge from the absorbed sunlight. An optional upper electrode layer is disposed over the conformal conductive layer. During operation, light beams entering the disordered nanowire cell are scattered by the disordered nanowire mat and absorbed by the p-i-n coating layer (e.g., freed electrons pass from the p-i-n coating layer along the nanowires to the lower electrode layer, and holes pass from the p-i-n coating layer through the conformal conductive layer to the upper electrode layer).

According to another embodiment of the present invention, a method for producing a disordered nanowire solar cell includes forming a disordered nanowire mat by subjecting a seed layer to the vapor-liquid-solid (VLS) processing technique at a high temperature (e.g., 450° C.) such that the resulting nanowires are disposed in a random interwoven pattern, and then forming a thin (e.g., 50 nm) p-i-n coating layer on the body and free end of each of the plurality of nanowires.

### BRIEF DESCRIPTION OF THE DRAWINGS

These and other features, aspects and advantages of the present invention will become better understood with regard to the following description, appended claims, and accompanying drawings, where:

FIG. 1 is a top and side perspective view showing a disordered nanowire solar cell according to a simplified embodiment of the present invention;

FIG. 2 is an enlarged photograph showing an exemplary disordered nanowire mat;

FIGS. 3(A), 3(B), 3(C), 3 (D), 3(E) and 3(F) are perspective views showing a process for generating a disordered nanowire solar cell according to another embodiment of the present invention;

FIG. 4 is a graph showing absorption of a disordered nanowire mat produced in accordance with the present invention;

FIG. 5 is a graph showing a calculated absorption spectrum for a 100 nm Si disordered nanowire mat coated with 50 nm of a-Si and a-SiGe in accordance with the present invention;

FIG. 6 is a graph showing optical absorption and charge collection in a conventional planar cell; and

FIG. 7 is a simplified diagram showing a conventional vertically structured solar cell.

### DETAILED DESCRIPTION OF THE DRAWINGS

The present invention relates to an improvement in vertically structured solar cells. The following description is presented to enable one of ordinary skill in the art to make and use the invention as provided in the context of a particular application and its requirements. As used herein, directional terms such as “upper”, “upwards” and “lower” are intended to provide relative positions for purposes of description, and are not intended to designate an absolute frame of reference. Various modifications to the preferred embodiment will be apparent to those with skill in the art, and the general principles defined herein may be applied to other embodiments. Therefore, the present invention is not intended to be limited to the particular embodiments shown and described, but is to be accorded the widest scope consistent with the principles and novel features herein disclosed.

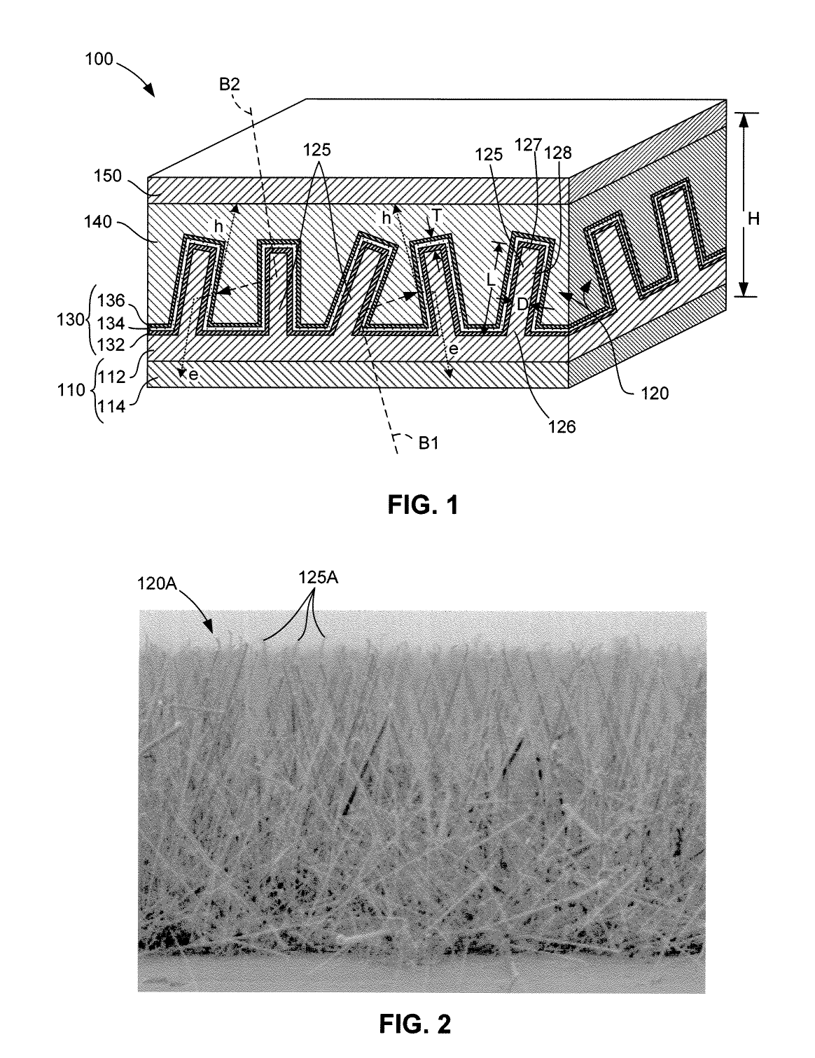

FIG. 1 is a cut-away perspective view showing a vertically structured, disordered nanowire solar cell 100 according to a simplified exemplary embodiment of the present invention. Solar cell 100 generally includes a substantially planar (first) electrode layer 110, a disordered nanowire mat 120 including a plurality of nanowires 125 disposed on electrode layer 110, a p-i-n coating layer 130 conformally disposed on each nanowire 125, a conductive layer 140 disposed on p-i-n coating layer 130, and an optional substantially planar (second) electrode layer 150 disposed on conductive layer 140. For reference purposes, the overall height H of solar cell 100 (e.g., measured between electrode layers 110 and 150) is in the range of 3 to 50 microns (μm). The above-mentioned structures of solar cell 100 and their functions are described in the following paragraphs.

Referring to the lower portion of FIG. 1, substantially planar electrode layer 110 includes a nanowire seed layer 112 and a conductive layer 114. Nanowire seed layer 112 includes the nanoparticle catalyst from which the nanowires grow and an optional silicon layer. The preferred catalyst is gold.

As set forth below, depending on the orientation of solar cell 100, the material utilized to form conductive layer 114 is either a reflective material, such as aluminum or silver, or a transparent material, such as indium-tin oxide (ITO).

Referring again to FIG. 1, disordered nanowire mat 120 includes a plurality of nanowires 125 that extend away from electrode layer 110. As indicated on the right side of FIG. 1, each nanowire 125 has a fixed end 126 connected to seed layer 112, a free end 127 disposed away from the seed layer 112, and a body 128 that extends between fixed end 126 and free end 127. In the preferred embodiment, nanowires 125 have a substantially cylindrical structure including a diameter D (measured across body 128) in the range of 20 to 300 nanometers (nm), and a length L (measured from free end 127 to fixed end 126) in the range of 1 to 30 μm. This silicon nanowire design serves as a suitable conductor, having a conductivity sufficient to support the solar cell current without significant voltage drop. The required conductivity, σ, depends on the nanowire diameter, D, length, L, and spacing, S. The solar cell current is about 0.02 S². The resistance of the wire is L/σD², so the condition is that 0.02 S²L/σD²<0.1V or σ>S²L/5D². For typical values this is ˜0.1 ohm cm (which is easily achieved with doped silicon). For example, assuming a 2 μm average separation of nanowires and 20% cell efficiency, the current in each nanowire is ˜1nA. A typical n-type silicon nanowire core of 100 nm diameter will draw this current with less than 10 μV resistive drop, and therefore makes an effective electrode.

According to an aspect of the present invention, disordered nanowire mat 120 serves as an optical scattering structure for solar cell 100. As used herein, the term “disordered nanowire mat” means an array of nanowires extending from a common seed layer in which the nanowires are caused to grow in random, different (e.g., non-parallel) directions such that substantially all of each nanowire extends in a non-perpendicular direction from the seed layer, and the nanowires are interwoven with adjacent nanowires to form a thick mass. FIG. 2 is an enlarged photograph showing an exemplary disordered nanowire mat 120A produced by the assignee of the present application in including silicon nanowires 125A extending from a planar substrate (not shown). The doped silicon seed layer used to form mat 120A was subjected to a temperature of 450° C. and exposed to a flow of silane and hydrogen gas in a chemical vapor deposition reactor for about 10 minutes in order to produce the pictured random interwoven pattern in which each nanowire 125A has a nominal diameter of 100 nm. As indicated in FIG. 2, substantially all of the resulting nanowires 125A of the pictured disordered nanowire mat are formed such that a significant portion (i.e., more than half, and as much as 95% or more of their body is bent (angled) away from perpendicular with respect to the underlying planar seed layer. Those skilled in the art will recognize the pictured random interwoven pattern characterizes a key distinction between the term “disordered nanowire mat”, as used and defined herein, and arrays of “ordered” or “semi-ordered” nanowires in which the nanowires are substantially parallel, and extend substantially perpendicularly from a planar substrate. The random interwoven pattern associated with disordered nanowire mat 125A, which represents a practical and accurate embodiment of disordered nanowire mat 125 (which is greatly simplified in FIG. 1 for explanatory purposes), represents a key feature associated with the effectiveness of solar cells produced in accordance with the present invention because the random interwoven pattern significantly scatters the incident light, causing each photon to interact with multiple nanowires, which greatly facilitates subsequent absorption by p-i-n coating layer 130.

Referring again to FIG. 1, p-i-n coating layer 130 is conformally disposed on free end 127 and at least a portion of body 128 of each nanowire 125. According to presently preferred embodiments, p-i-n coating layer 130 has a thickness in the range of 30 nm and 300 nm, and is formed by one of amorphous silicon (a-Si) and silicon germanium (SiGe). As indicated on the left side of FIG. 1, p-i-n coating layer 130 includes an inside (first) layer 132 that is disposed in contact with the outer surface of each nanowire 125, an outside (second) layer 136, and an intrinsic layer 134 sandwiched between the inside and outside layers. In one embodiment, inside layer 132 is a p-doped layer (e.g., crystalline Si doped with boron) and outside layer 136 is an n-doped layer (e.g., crystalline Si doped with phosphorous or arsenic). In an alternative embodiment, inside layer 132 is an n-doped layer and outside layer 136 is a p-doped layer. As used herein, “p-i-n coating layer” is intended to refer to either of these p-i-n or n-i-p embodiments. In a preferred embodiment, inside layer 132 and nanowires 125 are doped using the same dopant type (e.g., both inside layer 132 and nanowires are doped with boron in a p-i-n embodiment, or both inside layer 132 and nanowires are doped with phosphorus and arsenic in an n-i-p embodiment).

Referring again to FIG. 1, conformal conductive layer 140 includes a conductive material deposited in a way that operably contacts the portions of p-i-n coating layer 130 disposed on free ends 127 and at least a portion of body 128 of each nanowire 125 in order to collect charge from the absorbed sunlight. The conductive material needs to be effectively transparent, where “effectively transparent” is defined herein as sufficiently transparent so that conformal conductive layer 140 will not significantly absorb the part of the solar spectrum which is detected by p-i-n coating layer 130. The conductive material must also have refractive index different from the p-i-n coating and silicon nanowire, so that the light scattering effect is not prevented. The conductive material must also have sufficiently high conductivity the pass the solar cell current without significant voltage drop. A conductivity of greater than 0.1 Siemens per meter is therefore required.

In alternative embodiments, conformal conductive layer 140 includes a soluble or granular conductor (e.g., one of carbon nanotubes, organic or polymeric conductors, or a granular inorganic conductor) disposed in a solution or a dispersion that flows between nanowires 125 to carry the conductor into an operable position. In the disclosed embodiment, conformal conductive layer 140 is disposed between p-i-n coating layer 130 and optional electrode layer 150 such that conformal conductive layer 140 forms a conductive path for electronic charge flowing between outside (n-doped) layer 316 and electrode layer 150. In another embodiment electrode layer 150 may be omitted such that charge flow through conformal conductive layer 140 to one or more point electrodes (not shown). Those skilled in the art will recognize that other conductive materials may be utilized to perform the function of conformal conductive layer 140 that is described herein.

Referring to the upper and lower portions of FIG. 1, as indicated by dashed lined arrows 31 and 32, sunlight entering solar cell 100 from either side is scattered by nanowire mat 120 and absorbed by p-i-n coating layer 130 such that electrons (e) are conducted by nanowires 125 to first electrode layer 110, and holes (h) are conducted by conductive layer 140 to optional conductive layer 150. In the disclosed embodiment, the freed electrons flow to conductive layer 114, which is electrically connected to lower layer 132 of p-i-n coating layer 130 by way of nanowires 125 and seed layer 112, and the freed holes flow to upper electrode layer 150, which is electrically connected to upper layer 136 of p-i-n coating layer 130 by way of conformal conducting layer 140. In addition to serving as electrodes, conductive layer 114 and upper electrode layer 150 also function as optical structures to pass or reflect light within solar cell 120. For example, in one embodiment conductive layer 114 comprises a reflective material (e.g., aluminum or silver) and upper electrode layer 150 comprises a transparent material (e.g., ITO), thereby facilitating beams (e.g., beam 32) that enter solar cell 100 from the upper side of solar cell 100. Alternatively, conductive layer 114 may comprise a transparent material (e.g., ITO) and upper electrode layer 150 may comprise a reflective material (e.g., aluminum or silver), thereby facilitating beams (e.g., beam B1) that enter solar cell 100 from the lower side of solar cell 100.

As set forth above, the present invention introduces a new concept in vertical structured solar cells, based on the light scattering properties of disordered nanowire mat 120. The scattered light interacts with many nanowires 125, so that each nanowire cell has high charge collection while disordered nanowire mat 120 has optical absorption equivalent to a much thicker film. As set forth below, disordered nanowire solar cell 100 has a further advantage in that it is made from established solar materials and using large-area compatible fabrication processes, so that the low-cost manufacturing systems developed for large area electronics can be used in the production process. The combination of high efficiency, low materials usage and low manufacturing costs make disordered nanowire solar cell 100 a radical improvement over conventional solar cells, thereby facilitating a rapid transition from fossil fuel.

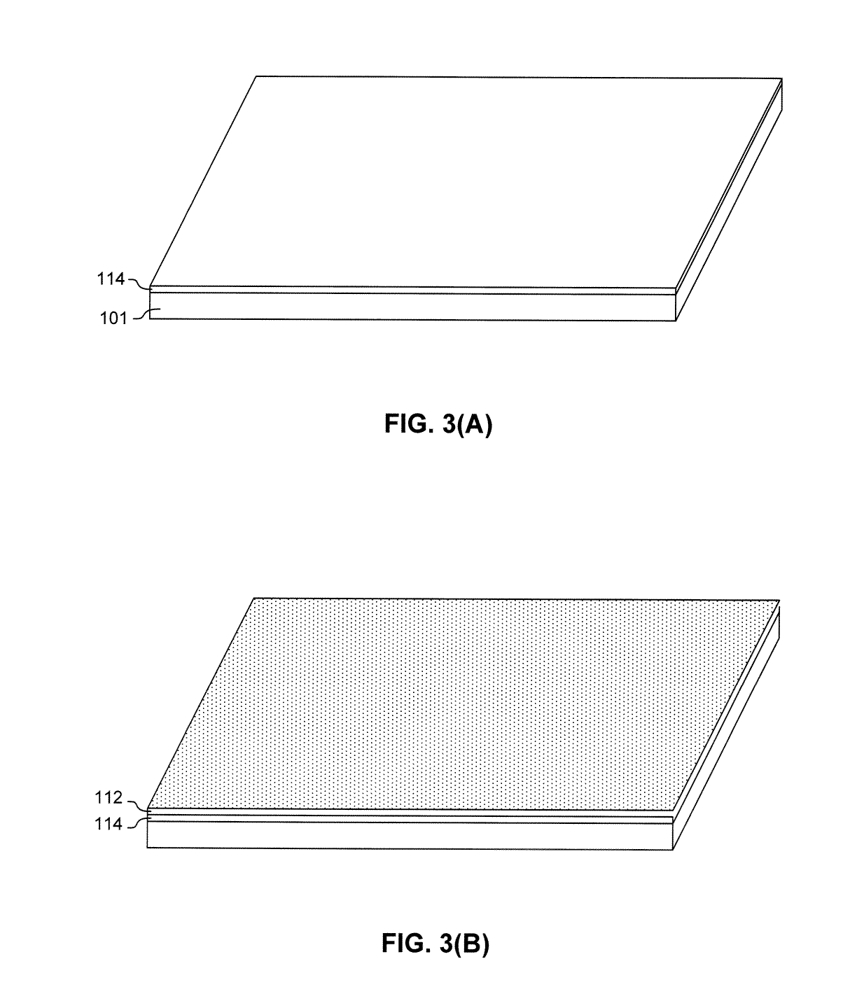

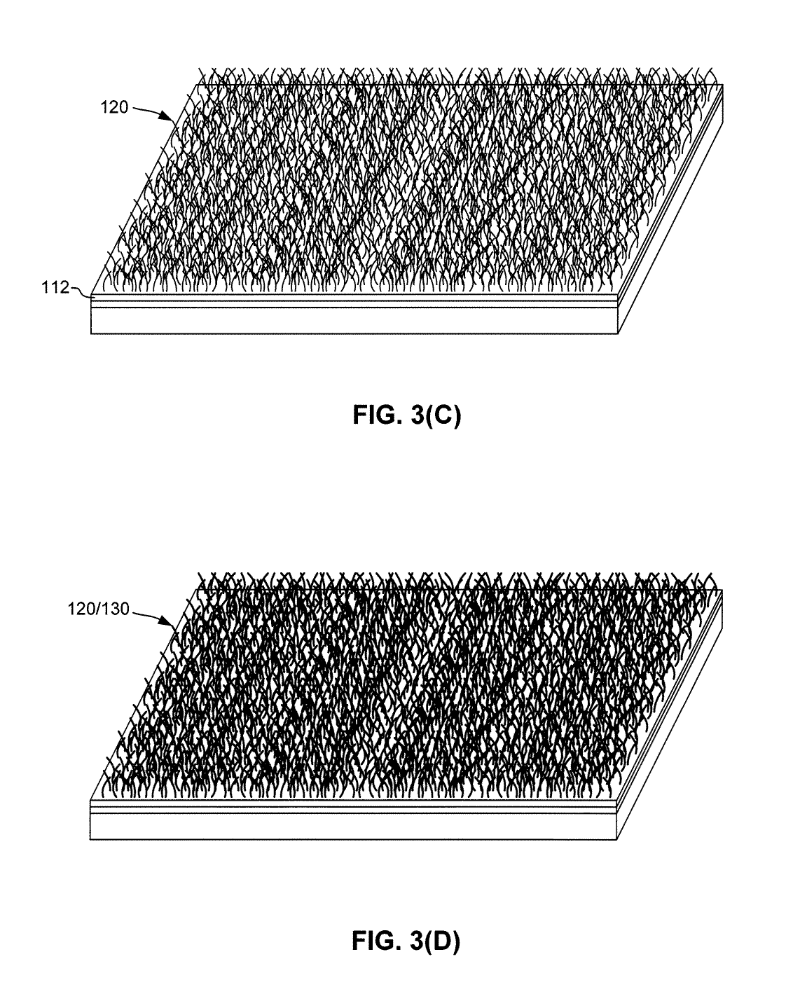

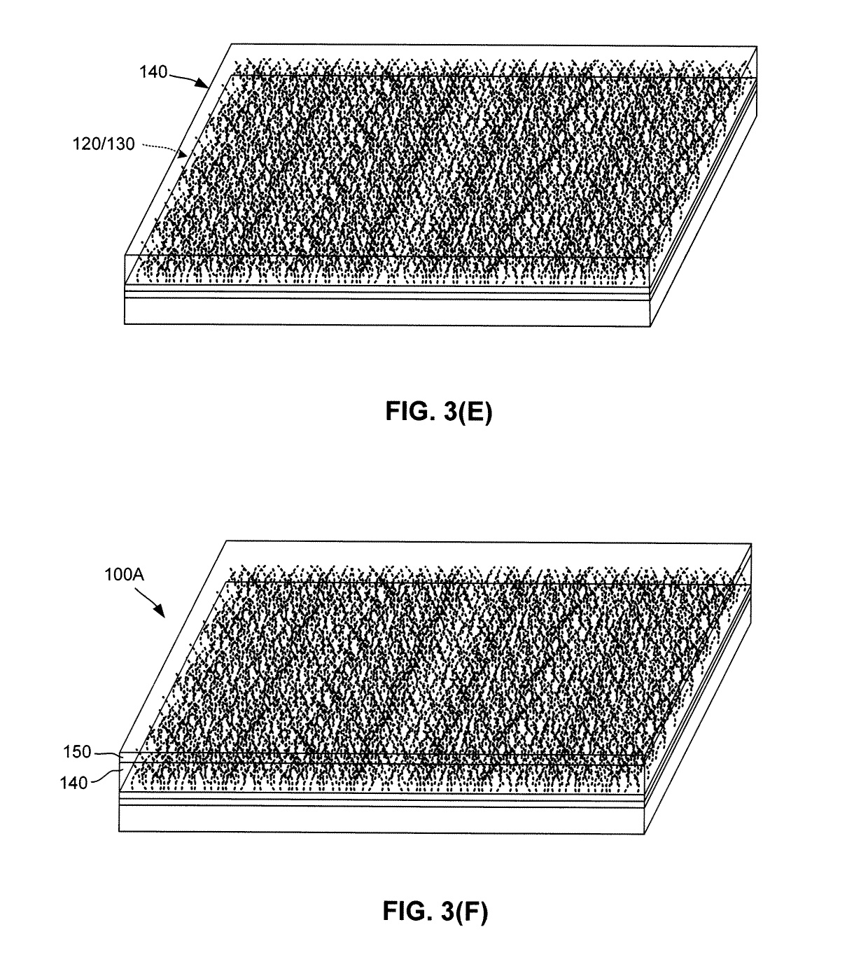

FIGS. 3(A)-3(F) are simplified perspective views showing a process for generating disordered nanowire solar cells according to another embodiment of the present invention.

Referring to FIG. 3(A), conductive layer 114 is formed, for example, by sputtering ITO onto a glass substrate 101 using known techniques. In an exemplary embodiment, glass substrate 101 has a thickness of 1 millimeter and a surface area of 1 meter by 1 meter or larger, and conductive layer 114 is formed with a thickness of 300 nm. An advantage to utilizing sputtered ITO to form conductive layer 114 is that this material is a mainstay of the display business, and scale-up to large area electronics is well-known. A flexible substrate (e.g., steel foil or high temperature plastic) may be used in place of glass substrate 101.

Referring to FIG. 3(B), seed layer 112 is then formed on conductive layer 114 by optionally depositing a doped silicon layer by chemical vapor deposition (CVD) utilizing known techniques, and then forming a catalyst (e.g., gold) by depositing a nanoparticle solution on the silicon layer. In the exemplary embodiment, the silicon layer has a thickness of 200 nm, and the catalyst nanoparticles have a diameter of 100 nm. The catalyst is required for nanowire growth.

Referring to FIG. 3(C), disordered nanowire mat 120 is then formed on seed layer 114, for example, by heating seed layer 112 to 450° C. and providing a precursor gas such as silane (5% in helium) for silicon nanowire growth. The precursor gas is introduced into the growth chamber with a gas flow between 5 sccm to 100 sccm with a carrier gas such as hydrogen or helium at a flow rate of 50 to 200 sccm. The pressure of the growth is controlled to be between 500 mTorr to 200 Torr. The disordering of the mat is controlled by the Si partial pressure, typically between 25 mTorr (minimum disorder) to 5 Torr (maximum disorder) by varying the ratio between silane and carrier gas flow and growth pressure. The growth of the nanowire then proceeds through the well known VLS growth process. As set forth above, the processing parameters are selected such that disordered nanowire mat 120 is formed on a seed layer 112 such that nanowires 125 are grown with a deposition rate of 1 μm/minute by CVD in a random interwoven pattern.

Referring to FIG. 3(D), p-i-n coating layer 130 is then formed over disordered nanowire mat 120 such that p-i-n coating layer 130 conformally coats the body and free end of the nanowires. In one embodiment, p-i-n coating layer 130 comprises a-Si deposited by PECVD using SiH₄ gas, and has a nominal thickness of approximately 50 nm, where forming the p-i-n layer further includes adding a p-type dopant (e.g., boron) during a first phase of the PECVD process to form a conformal p-layer of said p-i-n layer on a surface of the plurality of nanowires, forming a conformal intrinsic layer on the p-layer during a second phase of the PECVD process, and then including an n-type dopant (e.g., phosphorus or arsenic) during a third phase of the PECVD process to form a conformal n-layer of said p-i-n layer on a surface of the intrinsic layer. The deposition of a-Si by PECVD is known to result in conformal growth of the film on planar surfaces, and the inventors have demonstrated that coating a-Si on the nanowires of a disordered nanowire mat gives enhanced optical absorption due to the light scattering effect. Because depositing a-Si by PECVD is a mainstay of the display business, methods for forming p-i-n coating layer 130 and scaling-up the PECVD process to coat the nanowires over an area the size of substrate 101 would be understood by those skilled in the art. The thin a-Si device gives high charge collection and effectively eliminates the stability problems of a-Si, giving a more efficient cell that the planar equivalent. In an alternative embodiment, silicon-germanium (SiGe) using PECVD, which provides even greater efficiency of the resulting solar cell. The PECVD deposition of SiGe, results from combining SiH₄ and GeH₄ gasses in appropriate proportions.

Numerous variations in the materials used for the p-i-n solar cell that are known in the art can be applied to coating layer 130. The p- and n-doped layers may be made from a wider band gap a-Si alloy, such as a-SiC, or could be made from microcrystalline silicon, in order to minimize optical absorption in the doped layers. It is known two or three p-i-n layers in series can increase the solar cell efficiency, and such structures could be coated on the nanowires. It is also possible to use the nanowire as one of the doped layers, so that on a p-type nanowire, a conformal i-n layer is deposited, and similarly on an n-type nanowire, a conformal i-p layer is deposited. In principle the p-i-n conformal coating layer 130 could be any combination of materials that creates a solar cell.

Referring to FIG. 3(E), conformal conductive layer 140 is the formed over coated disordered nanowire mat 120/130 to collect charge. In one embodiment, forming conformal conductive layer 140 includes depositing a solution or dispersion including one of carbon nanotubes, organic conductors, or a granular inorganic conductor in a suitable solute (e.g., doped poly(3,4-ethylenedioxythiophene (PEDOT/PSS) in an aqueous solution, or a dispersion of tetraphenyldiamine (TPD) in a polycarbonate binder, both of which are sufficiently transparent and conducting).

Finally, as depicted in FIG. 3(F), method includes forming an upper conductive (electrode) layer 150 over conformal conductive layer 140. In the exemplary embodiment, forming upper conductive layer 150 comprises sputtering a reflective material (e.g., aluminum and silver) over the surface of conformal conductive layer 140.

As set forth above, the complete process can be fabricated by known large area compatible technology with large panel size to minimize cost. Roll-to-roll processing on a flexible substrate is also feasible.

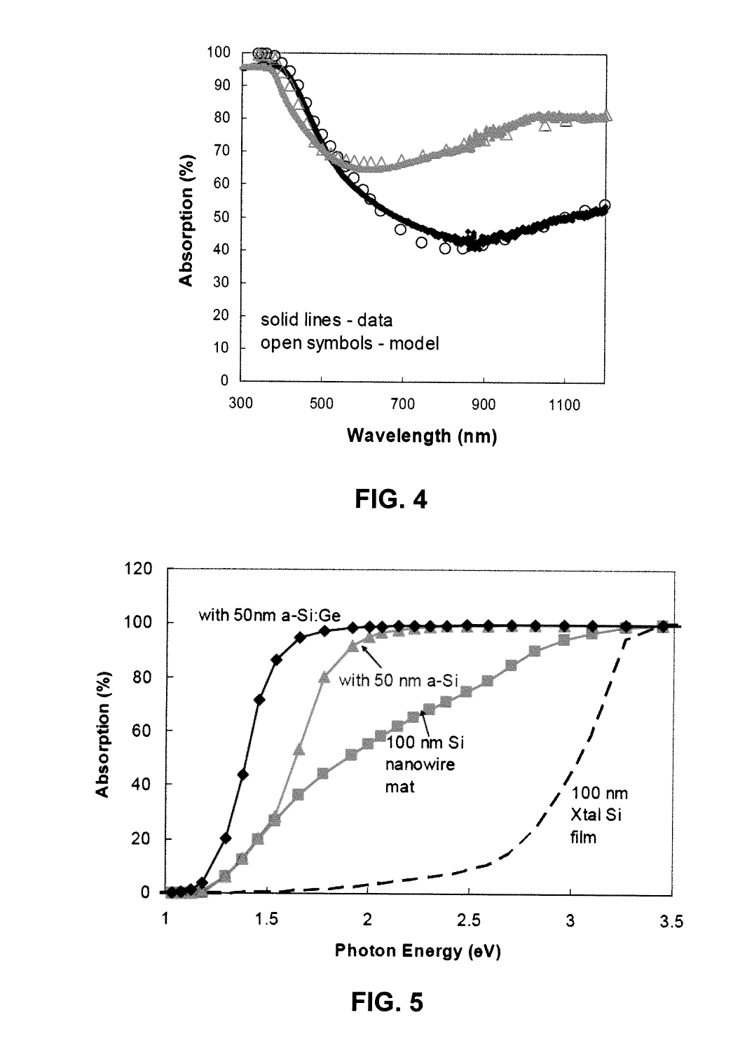

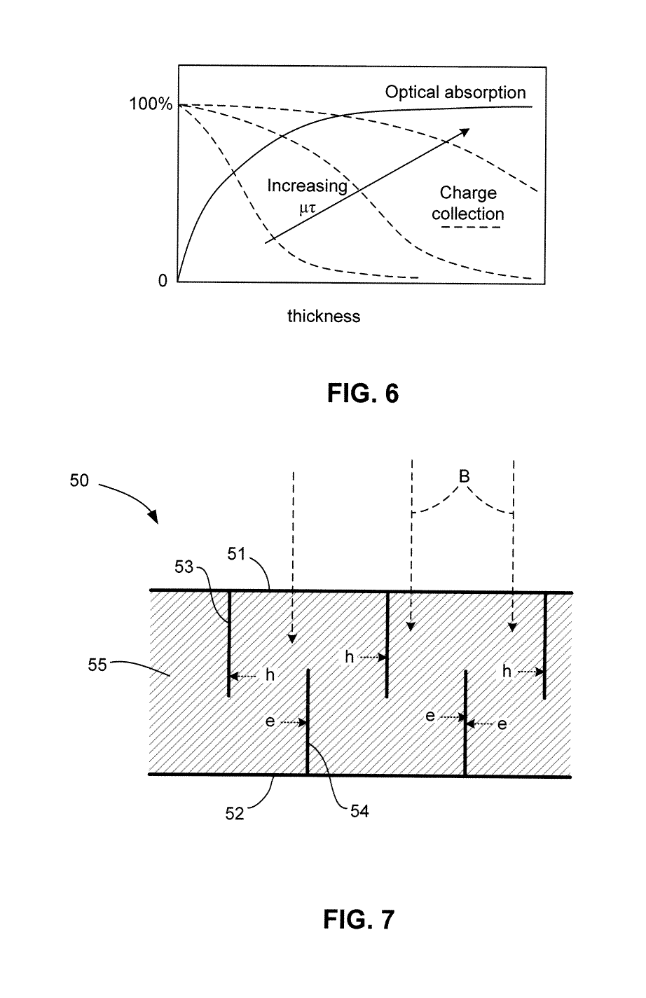

The disordered nanowire cells of the present invention are described by the function, p(N)˜exp(˜N/N₀), which is the probability of reflection after N scattering events. The inventors have shown that the absorption, A, reflectivity, R, and transmission, T, of light are modeled by equations (1) and (2), provided below:

$$\begin{matrix}\begin{matrix}A = 1 - R \\ = 1 - \frac{1}{{N}_{0}} {\int }_{0}^{∞} exp ( - N / {N}_{0} ) exp ( - N α {d}_{NW} ) d N \\ = \frac{{N}_{0} α {d}_{NW}}{1 + {N}_{0} α {d}_{NW}}\end{matrix} & ( 1 ) \\ T = \frac{1}{1 + {N}_{0} α {d}_{NW}} exp ( - σ w {λ}^{- 3} ) , & ( 2 )\end{matrix}$$

where α is the absorption coefficient of the wire, d_{NW} is the effective wire absorption depth, o is the scattering cross section, governed by Rayleigh-Mie theory and w is the mat thickness. N₀ is the average number of scattering events. FIG. 4 is a graph showing the reflectivity of two silicon mats grown on a silicon substrate, and the excellent fit of the model to the data, when the reflectivity and absorption of the substrate is also taken into account. The model shows that N₀ is about 30, so that when absorption is weak, a typical photon interacts with about 30 nanowires. Consequently, the effective absorption depth for the disordered nanowire solar cell is much larger than the thickness of the individual wire. A disordered nanowire solar cell thickness of 100 nm results in absorption equivalent to a three micron thick conventional device. This huge amplification results in a highly efficient cell.

Modeling shows that the effective absorption depth of disordered nanowire cells produced in accordance with the present invention is 30 times larger than that of individual nanowires, and a theoretical efficiency of 15-20% is predicted for a cell comprising a 50 nm amorphous silicon p-i-n layer conformally coated on the nanowires. The predicted absorption of the cell, comprising 100 nm silicon nanowires and with the addition of 50 nm thick a-Si and a-SiGe cells is shown in FIG. 5. The absorption extends below 1.5 eV on account of the thickness amplification effect. Furthermore, virtually all of the incident light is absorbed in the cell rather than the silicon nanowire, because the absorption coefficient of a-Si and a-SiGe is much larger than crystalline silicon over most of the spectrum. The inventors have confirmed the enhanced absorption of nanowires coated with a-Si.

One of the great benefits of being able to use a very thin a-Si layer is that charge collection is highly efficient. The charge collection length is L-prE, for a collection yield, E, and drift conditions. A charge collection figure of merit, FOM, is Lid:

FOM=μτE/d=μτV_{BI}/d² (3)

Estimating a built-in potential, VBI, of 0.5 V and typical μτ˜10-8 cm2/V for a-Si, gives FOM˜200 for a thickness of 50 nm. The 30× increase in effective absorption depth resulting from the use of the nanowire mat, changed the FOM by ˜1000×, compared to a planar device. This huge enhancement is the core advantage of the disordered nanowire cell, resulting in efficient charge collection and high stability. In addition, the enhancement enables the use of a lower band gap a-SiGe alloy to further increase the optical absorption.

Although the present invention has been described with respect to certain specific embodiments, it will be clear to those skilled in the art that the inventive features of the present invention are applicable to other embodiments as well, all of which are intended to fall within the scope of the present invention. For example, the future extension of the disordered nanowire solar cell concepts described herein to tandem cells can be anticipated, based on several alternative approaches; (1) forming a cell from the Si nanowire, (2) providing a second p-i-n a-Si alloy coating, and (3) providing an low band gap organic BHJ cell in the gap between nanowires. In addition, alternative cell designs based on the disordered nanowire mat are also possible.

1. A method for generating a solar cell comprising:
forming a disordered nanowire mat on a seed layer, the disordered nanowire mat including a plurality of nanowires disposed in a random interwoven pattern, each nanowire having a fixed end connected to said seed layer, a free end disposed away from the seed layer, and a body extending between the fixed end and the free end; and
forming a p-i-n coating layer over the disordered nanowire mat such that the p-i-n layer conformally coats at least a portion of the body and free end of each of the plurality of nanowires.

2. The method according to claim 1, wherein forming the nanowire mat comprises:
forming a seed layer on a conductive layer; and
processing the seed layer at 450° C. by chemical vapor deposition in flowing silane and hydrogen gas while controlling the disorder of the nanowire mat by controlling a partial pressure of the silane gas.

3. The method according to claim 2, wherein forming the seed layer comprises:
forming the conductive layer by sputtering Indium-Tin Oxide (ITO) onto a glass substrate;
forming a silicon layer by depositing silicon on the conductive layer using one of a sputtering process, an evaporation process, and a chemical vapor deposition process; and
forming a gold catalyst by depositing a nanoparticle solution on the silicon layer.

4. The method according to claim 1, wherein forming the p-i-n layer comprises depositing one of amorphous silicon (a-Si) and amorphous silicon-germanium (a-SiGe) using a plasma-enhanced chemical vapor deposition (PECVD) process.

5. The method according to claim 4, wherein forming the p-i-n layer further comprises:
including a p-type dopant during a first phase of the PECVD process to form a conformal p-layer of said p-i-n layer on a surface of the plurality of nanowires,
forming a conformal intrinsic layer on the p-layer during a second phase of the PECVD process, and
including an n-type dopant during a third phase of the PECVD process to form a conformal n-layer of said p-i-n layer on a surface of the intrinsic layer.

6. The method according to claim 1, further comprising depositing a conformal conductive layer onto the disordered nanowire mat.

7. The method according to claim 6, wherein depositing the conformal conductive layer comprises depositing a solution including one of (a) at least one of carbon nanotubes, organic conductors and granular inorganic conductor disposed in a suitable solute, and (b) a dispersion of tetraphenyldiamine (TPD) in a polycarbonate binder.

8. The method according to claim 6, further comprising forming a reflective conductive layer over the conformal conductive layer.

9. A method for generating a solar cell comprising:
forming a conductive layer on a substrate;
forming a seed layer on the conductive layer;
processing the seed layer by chemical vapor deposition in flowing silane and hydrogen gas while controlling a temperature of the seed layer and a partial pressure of the silane gas such that a disordered nanowire mat is formed on a seed layer, the disordered nanowire mat including a plurality of nanowires disposed in a random interwoven pattern, each nanowire having a fixed end connected to said seed layer, a free end disposed away from the seed layer, and a body extending between the fixed end and the free end; and
forming a p-i-n coating layer over the disordered nanowire mat such that the p-i-n layer conformally coats at least a portion of the body and free end of each of the plurality of nanowires.

10. A method for generating a solar cell comprising:
forming a conductive layer on a substrate;
forming a seed layer by depositing a silicon layer on the conductive layer using one of a sputtering process, an evaporation process, and a chemical vapor deposition process, and then forming a catalyst on the silicon layer;
heating the seed layer to a temperature of at least 450° C.;
processing the heated seed layer by chemical vapor deposition in flowing silane and hydrogen gas while controlling a partial pressure of the silane gas such that a disordered nanowire mat is formed on a seed layer, the disordered nanowire mat including a plurality of nanowires disposed in a random interwoven pattern, each nanowire having a fixed end connected to said seed layer, a free end disposed away from the seed layer, and a body extending between the fixed end and the free end;
forming a p-i-n coating layer over the disordered nanowire mat such that the p-i-n layer conformally coats at least a portion of the body and free end of each of the plurality of nanowires; and
forming a conformal conductive layer over the p-i-n layer by depositing a solution onto the disordered nanowire mat, the solution including one of (a) at least one of carbon nanotubes, organic conductors and granular inorganic conductor disposed in a suitable solute, and (b) a dispersion of tetraphenyldiamine (TPD) in a polycarbonate binder.
